(19) United States
(12) Patent Application Publication
(10) Pub. No.: US 2023/0166345 A1
(43) Pub. Date: Jun. 1, 2023

(54) ADAPTIVE INDUCTANCE COMPENSATION IN A WELDING CIRCUIT

(71) Applicant: ESAB AB, Gothenburg (SE)

(72) Inventor: Rolf Lennart Karlsson, Laxå (SE)

(21) Appl. No.: 17/537,644

(22) Filed: Nov. 30, 2021

(51) Int. Cl. B23K 9/10; G01R 19/25; B23K 9/09; B23K 9/095

(52) U.S. Cl. CPC B23K 9/1043; G01R 19/2506; B23K 9/09; B23K 9/095

(57) ABSTRACT

A method comprises: providing a welding current pulse through a welding circuit to create an arc for a welding operation; measuring an arc voltage to produce a measured arc voltage pulse that includes an inductive voltage drop due to inductance in the welding circuit and current ramps of the welding current pulse; and during the welding operation, implementing an inductance-compensation feedback loop. The feedback loop includes canceling the inductive voltage drop from the measured arc voltage pulse using a canceling voltage to produce a compensated arc voltage pulse; and deriving the canceling voltage based on the compensated arc voltage pulse.

### TECHNICAL FIELD

The present disclosure relates to welding circuit inductance compensation.

### BACKGROUND

Arc welding processes involve forming an electric arc between an electrode of a welding torch and a workpiece to deliver energy to the welding site. A welding power supply controls the power supplied to the welding torch via a welding power cable. In the case of Gas Metal Arc Welding (GMAW), such as Metal Inert Gas (MIG) and Metal Active Gas (MAG) welding processes, the welding power supply may be coupled via cabling to a wire feeder that is coupled to the welding torch by further cabling to feed a consumable electrode to the welding torch along with the welding power to be applied to the electrode. Accurate measurement of the welding current and a voltage of the arc (i.e., the “arc voltage”) enables more precise control of the welding process. While measuring welding current is generally straightforward, precisely determining the arc voltage is a significant challenge.

Various attempts have been made to more accurately determine arc voltage by measuring voltage in close proximity to the arc, but this approach typically requires additional sensors and feedback signals that add cost and complexity to the system. For example, welding systems that employ long welding cables, such as in submerged arc welding (SAW), may use external sense cables to measure the arc voltage. The external sense cables are configured to sense the arc voltage near the arc to reduce resistive voltage drop in the welding cables; however, undesired inductive coupling between the external sense cables and the welding cables distorts the sensed arc voltage.

Remotely measuring arc voltage at the welding power supply is more convenient but suffers from inaccuracies caused by resistance and inductance present between the power supply and the arc. Voltage variations caused by inductance can be particularly troublesome, because they fluctuate with changes in current, which are particularly prevalent in pulsed waveforms, and inductive effects may also vary throughout a welding operation as the physical arrangements of the welding power cable and the electrode change. While schemes have been proposed to estimate and compensate for these effects, there remains a need to more accurately determine arc voltage at a point in the system remote from the arc, such as at the power supply, and at a point near the arc.

### SUMMARY

A method is performed to compensate for inductance in a welding circuit during a welding operation. The method comprises: providing a welding current pulse through a welding circuit to create an arc for a welding operation; measuring an arc voltage to produce a measured arc voltage pulse that includes an inductive voltage drop due to inductance in the welding circuit and current ramps of the welding current pulse; and during the welding operation, implementing an inductance-compensation feedback loop. The inductance-compensation feedback loop performs operations that include canceling the inductive voltage drop from the measured arc voltage pulse using a canceling voltage to produce a compensated arc voltage pulse, and deriving the canceling voltage based on the compensated arc voltage pulse.

### BRIEF DESCRIPTION OF THE DRAWINGS

FIG. 1A is an illustration of an example welding system, according to an example embodiment.

FIG. 1B is a circuit diagram of an equivalent circuit for a welding circuit of the welding system, according to an example embodiment.

FIG. 2 shows current and voltage waveforms for a pulsed welding current and corresponding inductive voltage drop associated with the welding circuit, according to an example embodiment.

FIG. 3 shows voltage waveforms for an arc voltage pulse and a measured arc voltage pulse with inductive voltage drop in the form of overshoot and undershoot voltages, according to an example embodiment.

FIG. 4 is a circuit diagram of a welding system circuit that includes an inductance compensator to compensate for inductive voltage drop during a welding operation, according to an example embodiment.

FIG. 5 shows waveforms for welding current pulses and an inductance voltage/compensation signal derived by the inductance compensator, according to an example embodiment.

FIG. 6 shows a waveform for measured arc voltage pulses including overshoot and undershoot voltages created by the welding current pulses of FIG. 5 and welding circuit inductance, according to an example embodiment.

FIG. 7 shows waveforms of a canceling voltage derived by the inductance compensator based on the inductance voltage of FIG. 5, and measured arc voltage pulses with overshoot and undershoot voltages, according to an example embodiment.

FIG. 8 shows a waveform of a compensated arc voltage after canceling of overshoot and undershoot voltages using the canceling voltage of FIG. 7, according to an example embodiment.

FIG. 9 is a flowchart of a method of compensating for inductive voltage drop in a measured arc voltage pulse in a welding circuit using an inductance-compensation feedback loop, according to an example embodiment.

FIG. 10 is a block diagram of an inductance indicator of the inductance compensator, according to an example embodiment.

FIG. 11 shows a current waveform of example current pulses having rising and falling ramps, according to an example embodiment.

FIG. 12 shows voltage waveforms for measured and real arc voltages corresponding to the current waveform of FIG. 11 and the inductance indicator of FIG. 10, according to an example embodiment.

Like numerals identify like components and/or signals throughout the figures.

### DETAILED DESCRIPTION

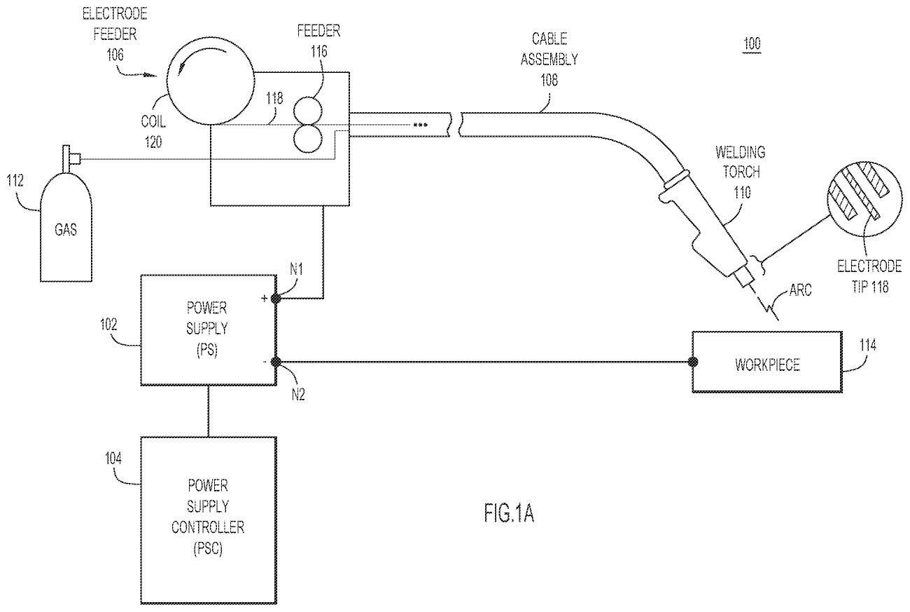

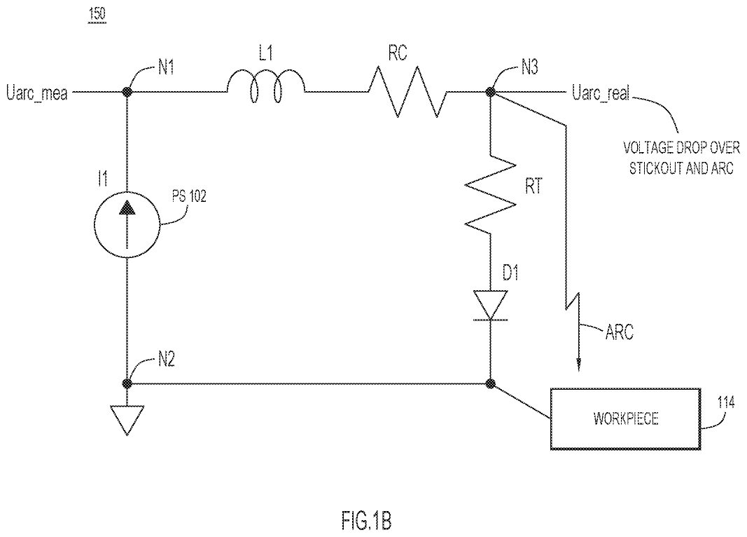

With reference to FIG. 1A, there is an illustration of an example MIG/MAG welding system 100, in which embodiments presented herein may be implemented. The embodiments are presented in the context of GMAW (e.g., MIG/MAG welding) by way of example only. It is understood that the embodiments may be employed generally in any known or hereafter developed welding environments, such as, but not limited to, tungsten inert gas (TIG) welding, flux cored arc welding (FCAW), shielded metal arc welding (SMAW), also known as Manual Metal Arc (MMA) welding or “stick” welding, submerged arc welding (SAW), and so on. Additionally, the embodiments may be employed equally in an arc cutting apparatus. Welding system 100 includes: a welding power supply 102, such as a switching power supply; a power supply controller (PSC) 104 coupled to and configured to control the power supply; a wire electrode feeder 106 coupled to the power supply; a cable assembly 108 coupled to the electrode feeder; a welding gun or torch 110 coupled to the cable assembly; a gas container 112 coupled to the cable assembly; and a workpiece 114 coupled to the power supply. It will be appreciated that wire electrode feeder 106 is applicable in the context of GMAW. In other types of arc welding, such as TIG welding or SMAW, power can be supplied from the welding power supply 102 directly to the welding gun or torch 110 via the cable assembly 108, and the wire electrode feeder 106 is omitted. In the ensuing description, the terms “weld” and “welding” are synonymous and interchangeable. Also, the terms “weld” and “welding” refer broadly to both welding and plasma cutting systems and operations.

Wire electrode feeder 106 includes a feeder 116 to feed an electrode 118 from a coiled electrode 120 to welding torch 110 through cable assembly 108. Under control of PSC 104, power supply 102 generates welding current that drives the welding process/operation. In welding operations that involve a pulsed or periodic waveform, the welding current typically includes a series of welding current pulses. Power supply 102 provides/delivers the welding current from an output node or terminal N1 of the power supply to welding torch 110 through electrode feeder 106 and cable assembly 108, while the cable assembly also delivers a shielding gas from gas container 112 to the welding torch 110.

The welding current creates an arc between workpiece 114 and a tip of electrode 118 (referred to as an “electrode tip,” “electrode stick,” or simply “stickout”) extending from welding torch 110. To control the welding process, PSC 104 controls the welding current based in part on a voltage of the arc (i.e., an arc voltage). Thus, it is important for PSC 104 to acquire an accurate measurement of the arc voltage throughout the welding process. Because it may be impractical or inconvenient to sense the arc voltage directly at the arc itself in some arrangements, an arc voltage measurement may be made without sense voltage equipment near the arc. For example, the arc voltage measurement may be made at a voltage sense point spaced-apart from the arc by a substantial distance along a circuit path of welding system 100 through which the welding current flows when the arc is present. In other arrangements, an arc voltage measurement may be made using sense voltage equipment (e.g., external sense cables) coupled to the circuit path near the arc. The aforementioned circuit path is referred to as a “welding circuit,” and may include, for example, a circuit path from node N1 of power supply 102 to a return node or terminal N2 of the power supply, through electrode feeder 106, cable assembly 108, welding torch 110, workpiece 114, and a return path from workpiece 114 to node N2.

The arc voltage measurement made at the voltage sense point differs from the arc voltage due to one or more voltage drops that are a function of the welding current, which changes dynamically, and one or more electrical circuit parameters or characteristics of the welding circuit through which the welding current flows. For example, the arc voltage may differ from the arc voltage measurement due to resistive and inductive voltage drops arising from a resistance and an inductance of the welding circuit. Accordingly, embodiments presented herein are directed to continuous or repetitive compensation of inductive voltage drop in the welding circuit during the welding process based on measurements of the arc voltage made in the welding circuit at a distance from the arc.

With reference to FIG. 1B, there is an illustration of an example equivalent circuit 150 for the above-mentioned welding circuit. Equivalent circuit 150 includes a resistance RC and an inductance L1 of the welding circuit connected in series between (output) node N1 and a node N3 that represents the electrode tip at welding torch 110. Equivalent circuit 150 includes a resistance RT and diode D1 to represent resistance and a voltage drop across the stickout and arc during the welding process. Power supply 102 supplies welding current I1 to welding torch 110 through resistance RC and inductance L1, which cause respective resistive and inductive voltage drops. Welding current I1 produces an arc voltage Uarc_real at node N3, which creates an arc. Arc voltage Uarc_real may be measured or sensed at node N1, spaced-apart from the arc, to produce a measured arc voltage Uarc_meas.

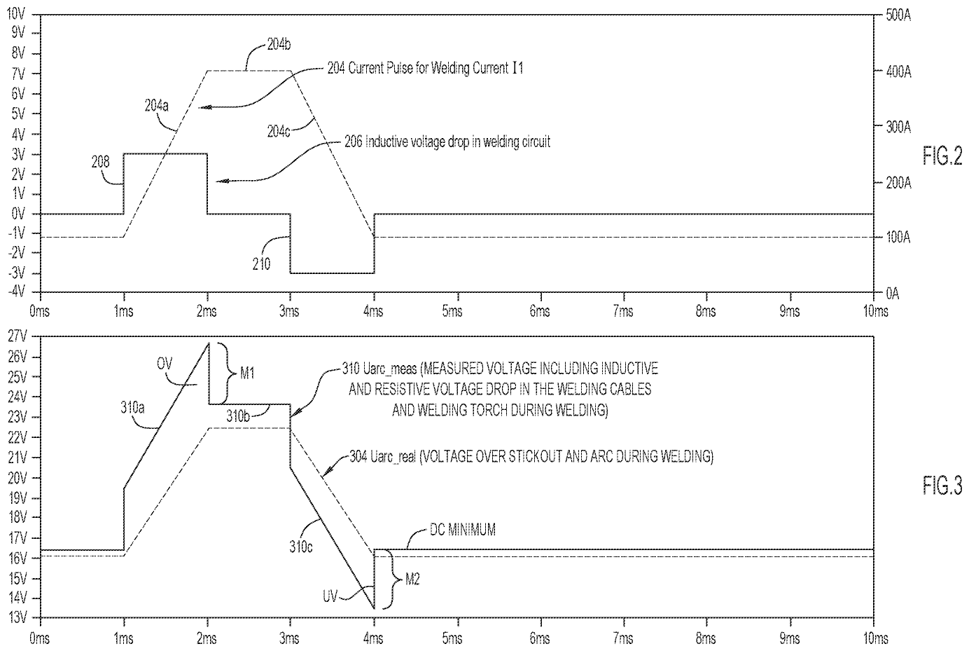

FIG. 2 shows example waveforms for welding current I1 and an inductive voltage drop 206 associated with the welding circuit/equivalent circuit 150. Welding current I1 includes a sequence of substantially similar welding current pulses (also referred to simply as “current pulses”) for a corresponding sequence of welding operations. One such welding current pulse 204 is shown in FIG. 2. Current pulse 204 has a fast rising current ramp 204a that rises from a minimum direct current (DC) level (i.e., a constant or flat current level for which di/dt=0 or near 0) to a DC current peak 204b that has a constant current level for which di/dt=0 or near 0, followed by a fast falling current ramp 204c that falls from the DC current peak to the minimum DC level. That is, rising and falling current ramps 204a, 204c straddle DC current peak 204b. In the example of FIG. 2, welding current I1 ramps up from 100 Amps (A) to 400 A in 1 millisecond (ms), remains constant at 400 A for 1 ms, and then ramps down to 100 A in 1 ms. Other current levels and ramp-up, DC peak, and ramp-down times are possible. In the ensuing description, a “current ramp” and a “DC current peak” may be referred to simply as a “ramp” and a “DC peak,” respectively. As used herein, the term “DC” refers to a constant or flat level, i.e., a level having zero or near zero slope.

Inductive voltage drop 206 includes a positive inductive voltage drop (pulse) 208 and a negative inductive voltage drop (pulse) 210 caused by inductance L1 of welding circuit/equivalent circuit 150 and the fast changing current levels (i.e., the steep slopes) of rising ramp 204a and falling ramp 204c of current pulse 204, respectively.

Positive and negative voltage pulses 208, 210 are time-aligned (i.e., coincide in time) with rising and falling ramps 204a, 204c of current pulse 204, respectively, and are thus spaced-apart by a duration of DC peak 204b of the current pulse. Positive and negative voltage pulses 208, 210 have respective DC peaks that extend above and below a minimum DC level (e.g., 0 volts). More specifically, positive and negative voltage pulses 208, 210 each has a respective magnitude given by inductance (L1)*di/dt, where di/dt is the slope of the rising/falling ramp 204a/204c of current pulse 204. As used herein, the term “DC” in the context of a pulse refers to a relatively flat level of the pulse, i.e. a level that has zero or near-zero slope.

FIG. 3 shows voltage waveforms for arc voltage Uarc_real and measured arc voltage Uarc_meas created by/corresponding to current pulse 204. Arc voltage Uarc_real includes a voltage pulse 304 time-aligned with and shaped similarly to current pulse 204. That is, arc voltage Uarc_real includes rising and falling voltage ramps that straddle a DC voltage peak that has a constant voltage level for which dv/dt=0 or near 0. In contrast, measured arc voltage Uarc_meas deviates from arc voltage Uarc_real due to resistive and inductive voltage drops in welding circuit 150. Measured arc voltage Uarc_meas includes a voltage pulse 310 (also time-aligned with current pulse 204) that includes a rising voltage ramp 310a, a DC voltage peak 310b that has a constant voltage level for which dv/dt=0 or near 0, and a falling voltage ramp 310c. Rising voltage ramp 310a extends above DC voltage peak 310b (i.e., exceeds the DC voltage peak in a positive direction) by an overshoot voltage OV due to positive voltage pulse 208. Overshoot voltage OV has a magnitude M1 equal to a difference between levels of DC voltage peak 310b and a sharp peak of the overshoot voltage. Similarly, falling voltage ramp 310c extends below a minimum DC voltage level (i.e., exceeds the minimum DC voltage level in a negative direction) by an undershoot voltage UV due to negative voltage pulse 210. Undershoot voltage UV has a magnitude M2 equal to a difference between levels of the minimum DC voltage level and a sharp peak of the undershoot voltage. Magnitudes M1 and M2 are each given by L1*di/dt, where di/dt is a slope of rising ramp 204a and falling ramp 204c of current pulse 204. In the ensuing description, a “voltage ramp” and a “DC voltage peak” may be referred to simply as a “ramp” and a “DC peak,” respectively.

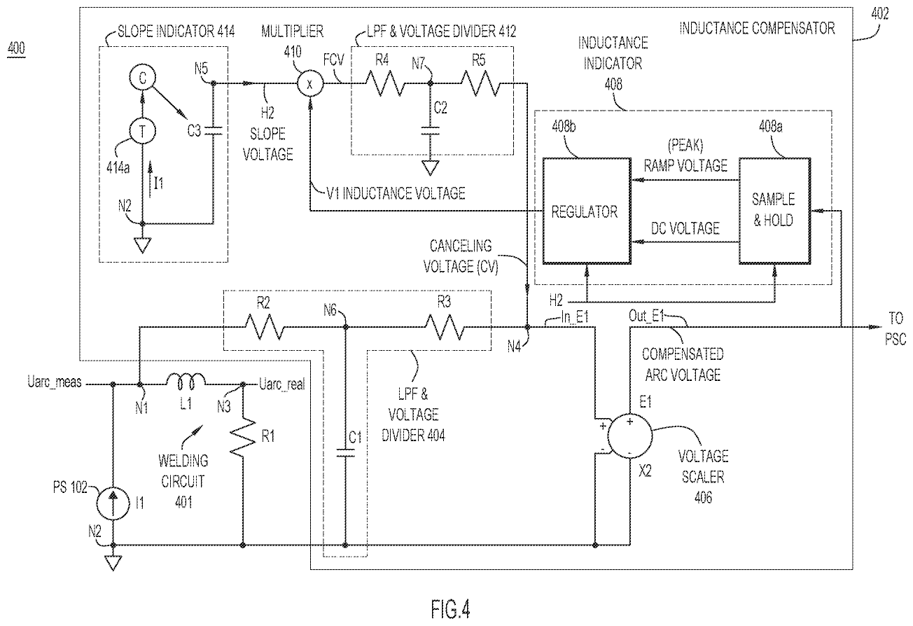

FIG. 4 is a schematic diagram of welding system circuit 400 that includes power supply 102, a simplified equivalent welding circuit 401 coupled to the power supply, and an inductance compensator 402 to perform adaptive compensation of inductance of the welding circuit, according to embodiments presented herein. Inductance compensator 402 may be incorporated into PSC 104, wholly or partly. Welding circuit 401 is a simplified version of welding circuit 150, and is coupled to power supply 102 at nodes N1 and N2. Welding circuit 401 includes inductance L1 coupled between nodes N1 and N3 to represent inductance of various welding system components, such as a welding cable, for example, and a resistance R1 coupled between nodes N3 and N2 to represent resistance of the welding system components and the welding arc.

Inductance compensator 402 includes a first lowpass filter (LPF) and voltage divider 404 coupled to nodes N1, N2, and an intermediate summing node N4, a voltage scaler 406 coupled to nodes N4 and N2, an inductance indicator or estimator 408 coupled to the voltage scaler, a multiplier 410 coupled to the inductance indicator, and a second LPF and voltage divider 412 coupled to the multiplier. In addition, inductance compensator 402 includes a current slope indicator 414 coupled to power supply 102 and a node N5, which is coupled to multiplier 410. At a high-level, the aforementioned components of inductance compensator 402 implement an inductance-compensation feedback loop (also referred to simply as a “feedback loop”) that continuously compensates for inductance L1 of welding circuit 401 during a welding operation. That is, the feedback loop cancels inductive voltage drop from a measured arc voltage. The feedback loop repeatedly performs:
a. Measuring (e.g., at node N1) a voltage of the arc voltage generated by the welding current to produce the measured arc voltage (Uarc_meas), which includes the inductive voltage drop due to inductance L1 of the welding circuit and current ramps of welding current pulses of the welding current.
b. Canceling the inductive voltage drop from the measured arc voltage using a canceling voltage, to produce a compensated arc voltage pulse.
c. Deriving the canceling voltage based on a magnitude of uncanceled inductive voltage drop remaining in the compensated arc voltage after the canceling. More specifically, the deriving includes (i) measuring the magnitude of the uncanceled inductive voltage drop, and deriving an indication of inductance L1 based on the measured magnitude, (ii) deriving an indication of a slope of the current ramps (di/dt), and (iii) deriving the canceling voltage based on the indications of the inductance and the slope.

The feedback loop initially operates in a non-steady state condition, and then transitions to a steady condition over successive passes or cycles through the feedback loop. The non-steady state condition may occur during initial startup- or reset of inductance compensator 402, or when inductance L1 of welding circuit 401 changes. The inductance changes as welding cable lengths or electrode lengths change, for example. Such changes occur relatively slowly compared to the amount of time taken by the feedback loop to transition from the non-steady state condition initiated by the changes to the steady state condition. The non-steady state condition includes one or more initial passes or cycles through the feedback loop when the canceling voltage does not accurately reflect the inductive voltage drop, and therefore does not cancel the entire inductive voltage drop in welding circuit 401. Beginning in the non-steady state condition, successive passes through the feedback loop result in successive adjustments to the canceling voltage so that it more accurately reflects the inductive voltage drop with each pass and eventually cancels substantially all of the inductive voltage drop. The successive passes drive the feedback loop to the steady state condition, when substantially all of the inductive voltage is canceled.

The operation of inductance compensator 402 is now described in detail. Power supply 102 supplies successive current pulses of welding current I1 through welding circuit 401 for corresponding successive welding operations or cycles. The current pulses produce corresponding arc voltage pulses of Uarc_real at node N3. The arc voltage is sensed/measured at node N1 to produce measured arc voltage pulses of measured arc voltage Uarc_real. The feedback loop of inductance compensator 402 operates repeatedly, i.e., cycles repeatedly, over time across the measured arc voltage pulses, to cancel inductive voltage drop (e.g., overshoot and undershoot voltages OV and UV) from each of the measured arc voltage pulses; however, operation of the inductance compensator is described below primarily for one current pulse (and measured arc voltage pulse), since that operation essentially repeats for each current/voltage pulse. For example, the operation is described for current pulse 204, voltage pulse 304 of arc voltage Uarc_real, and voltage pulse 310 of measured arc voltage Uarc_meas corresponding to the current pulse.

Power supply 102 supplies current pulse 204 of welding current I1 to node N1. Node N1 provides measured arc voltage pulse 310, which arises due to current pulse 204, to first LPF and voltage divider 404 (described below). Concurrently, current slope indicator 414 derives a slope voltage H2 that is indicative of (e.g., proportional to) the slope of current I1 (e.g., of current pulse 204), and provides the slope voltage to a first input of multiplier 410. Current slope indicator 414 may be integrated with power supply 102 (e.g., connected between nodes N1 and N2, but is shown separately in FIG. 4 for clarity).

Current slope indicator 414 includes a current transducer (T) 414a coupled to power supply 102 and through which at least some of current I1 flows, a converter C coupled to the current transducer, and a capacitor C3 coupled to the converter, node N5, and return node N2. Current transducer 414a and converter C collectively convert welding current I1 to a slope voltage H2, and apply the slope voltage to capacitor C3. In turn, capacitor C3 applies slope voltage H2 (referred to more generally as a “slope signal”) to node N5. Slope voltage H2 is proportional to the slope of welding current I1 at any given time, but with an opposite polarity to measured arc voltage Uarc_meas, i.e., H2α−di/dt. For example, voltage H2 has (i) a negative value that is proportional to a positive slope of rising ramp 204a of current pulse 204 during the rising ramp, (ii) a zero value that represents the flat slope of DC peak 204b of the current pulse during the DC peak, and (iii) a positive value that is proportional to a negative slope of falling ramp 204c. Node N5 applies slope voltage H2 to the first input of multiplier 410.

First LPF and voltage divider 404 receives voltage pulse 310 of measured arc voltage Uarc_meas. Measured arc voltage Uarc_meas (e.g., measured arc voltage pulse 310) includes inductive voltage drop in the form of overshoot and undershoot voltages OV and UV, as described above. First LPF and voltage divider 404 includes series connected resistors R2 and R3 configured as a voltage divider, and a capacitor C1. Resistor R2 is connected to node N1 and an intermediate node N6, resistor R3 is connected to node N6 and node N4, and capacitor C1 is connected to node N6 and return node N2. While current slope indicator 414 derives slope voltage H2, first LPF and voltage divider 404 lowpass filters measured arc voltage Uarc_meas. The LPF has a lowpass filter cutoff or 3 dB bandwidth low enough to reduce high-frequency noise, voltage ripple, and harmonics of measured arc voltage Uarc_meas, but high enough to preserve the general shape of voltage pulse 310, including its ramps, and overshoot and overshoot voltages. Additionally, first LPF and voltage divider 404 scales or divides-down the amplitude of measured arc voltage Uarc_meas, to provide to node N4 a (filtered) reduced-amplitude measured arc voltage (e.g. a scaled version of voltage pulse 310), which retains overshoot and undershoot voltages OV and UV. In an example, first LPF and voltage divider 404 scales-down the amplitude by a factor of 2, although other scaling factors are possible. In another embodiment, first LPF and voltage divider 404 may be omitted, and in yet another embodiment, the voltage divider may be omitted, leaving only the LPF. When the voltage divider is omitted, voltage scaler 406 may also be omitted.

At node N4 (which is a voltage summing node), the reduce-amplitude measured arc voltage (e.g., scaled version of voltage pulse 310) is summed with a canceling voltage CV derived by the feedback loop of inductance compensator 402 in the manner described herein, to cancel the overshoot and undershoot voltages OV and UV (as scaled) of the measured arc voltage, to produce a reduced-amplitude compensated arc voltage In_E1. Next, in order to compensate for the scale-down operation of first LPF and voltage divider 404, voltage scaler 406 scales-up (e.g., by a factor of 2) reduced-amplitude compensated arc voltage In_E1 to produce compensated arc voltage Out_E1, and provides the compensated arc voltage to inductance indicator 408

Inductance indicator 408 includes a sample-and-hold module 408a followed by a regulator 408b. At a high-level, sample-and-hold module 408a and regulator 408b operate to (i) derive an inductance voltage V1 (also referred to a “compensation signal V1”) indicative of inductance L1 based on a measured magnitude of the uncanceled inductive voltage drop (e.g., the magnitudes of uncanceled overshoot and undershoot voltages on rising and falling ramps of the measured arc voltage pulse 310/Uarc_meas) remaining in compensated arc voltage Out_E1 after the canceling at nulling node N4, and (ii) provides inductance voltage V1 to a second input of multiplier 410.

During an initial pass through the feedback loop before it is operating in the steady state condition, canceling voltage CV does not accurately reflect the inductive voltage drop and does not cancel substantially the entire inductive voltage drop. Therefore, compensated arc voltage Out_E1 may essentially be a replica of measured arc voltage pulse 310. In that case, for the overshoot voltage, sample-and-hold module 408a measures (i) a positive peak level of/corresponding to overshoot voltage OV (denoted “peak ramp voltage” in FIG. 4) on rising ramp 310a, and (ii) a DC level corresponding to/of DC peak 310b (denoted “DC voltage” in FIG. 4) above which the overshoot voltage extends, and provides the two levels to regulator 408b, in parallel. The overshoot voltage and the DC (peak) voltage should be measured close to each other in time so that real arc voltage Uarc_real does not change or changes as little as possible between the measurements. A difference between the two levels represents a measured magnitude of the overshoot voltage. Regulator 408b derives inductance voltage V1 at least based in part on the difference between the two levels, (e.g., based on magnitude M1 of overshoot voltage OV). For example, regulator 408b derives inductance voltage V1 to be proportional to inductance L1 based on the measured magnitude of the overshoot voltage.

Similarly, for the undershoot voltage, sample-and-hold module 408a measures (ii) a negative peak level of undershoot voltage UV (denoted “peak ramp voltage” in FIG. 4) on falling ramp 310c, and (ii) a minimum DC level (denoted “DC voltage”) and provides the two levels to regulator 408b, in parallel. Regulator 408b derives inductance voltage V1 based on a difference between the two levels (e.g. based on magnitude M2 of undershoot voltage UV). For example, regulator 408b derives inductance voltage V1 to be proportional to inductance L1 based on the measured magnitude of the undershoot voltage.

In an embodiment, inductance indicator 408 may receive slope voltage H2 from current slope indicator 414, and use the slope voltage to time/trigger the above-described peak and DC voltage level measurements. For example, sample-and-hold module 408a may include logic that is responsive to slope voltage H2. When slope voltage H2 exceeds a threshold value that indicates the presence of a current ramp, the logic triggers sample-and-hold module 408a to perform a peak detect/measurement operation to measure the peak level of the overshoot/undershoot voltage. Subsequently, when slope voltage H2 settles to zero, indicating the presence of the DC peak or the DC minimum level of measured arc voltage Uarc_meas, sample-and-hold module 408a performs the DC level measurement.

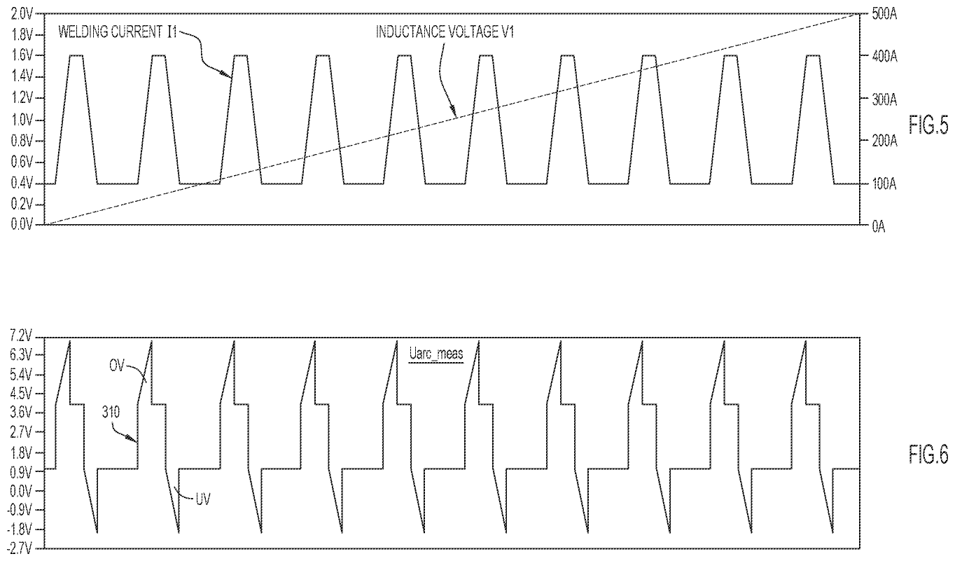

After the initial pass through the feedback loop, inductance indicator 408 operates similarly for successive passes through the feedback loop. In each pass, regulator 408b adjusts inductance voltage/compensation signal V1 based on the magnitude of the uncanceled inductive voltage drop (e.g., the difference between the peak ramp voltage and the DC voltage described above) remaining from the previous pass, so that canceling voltage CV more accurately reflects the inductive voltage drop in the next pass. Thus, regulator 408b increases and decreases inductance voltage V1 when compensated arc voltage Out_E1 is undercompensated (i.e., when canceling voltage CV is too small to cancel the inductive voltage drop, fully) and overcompensated (i.e., when canceling voltage CV is too big), respectively; the target being to keep compensated arc voltage V1 correct without over- or under-shoot when welding current I1 is changing. Under compensation and overcompensation are further described below in connection with FIGS. 5-8. Successive passes through the feedback loop drive inductance voltage V1 to a settled value that accurately represents inductance in the welding circuit. That value results in a canceling voltage that eliminates the overshoot and undershoot voltages.

Multiplier 410 multiplies together slope voltage H2 provided by current slope indicator 414 and inductance voltage V1 provided by inductance indicator 408, to produce a full-scale (F) canceling voltage (CV) FCV. Because slope voltage H2α di/dt and inductance voltage V1α L1, full-scale canceling voltage FCV α L1*di/dt, and thus represents (e.g., is proportional to) the inductive voltage drops exhibited by overshoot and undershoot voltages OV and UV, while the overshoot and undershoot voltages are present. Otherwise, FCV=0, due to the zero slope of the DC peak and DC minimum levels of the current pulse. More specifically, with respect to the inductive voltage drop, canceling voltage CV includes (i) an overshoot canceling voltage (waveform) that is time-aligned with overshoot voltage OV, and that is equal in magnitude and opposite in polarity (i.e. opposite in sign) to the overshoot voltage, and (ii) an undershoot canceling voltage (waveform) that is time-aligned with undershoot voltage UV, and that is equal in magnitude and opposite in polarity (i.e. opposite in sign) to the undershoot voltage.

Multiplier 410 provides full-scale canceling voltage FCV to an input of second LPF and voltage divider 412. Second LPF and voltage divider 412 includes series connected resistors R4 and R5, and a capacitor C2. Resistor R4 is connected to the output of multiplier 410 and an intermediate node N7, resistor R5 is connected to node N7 and node N4, and capacitor C2 is connected to node N7 and return node N2. Second LPF and voltage divider 412 lowpass filters and divides-down the amplitude of full-scale canceling voltage FCV to produce canceling voltage CV. As described above, canceling voltage CV is summed with the reduced-amplitude measured arc voltage at node N4. Once the feedback loop has settled, the overshoot and undershoot canceling voltages of canceling voltage CV cancel substantially all of the overshoot and undershoot voltages in reduced-amplitude compensated arc voltage In_E1, and thus in compensated arc voltage Out_E1.

In an example, R2, R3, R4, and R5 may each be equal to approximately 10 kΩ, and R1 may be many orders of magnitude less than that value, although other resistance values are possible. Also, C1 and C2 may be equal to each other in an embodiment, although they may be different from each other in another embodiment.

An advantage of the feedback loop is that it fast. That is, the feedback loop can drive inductance voltage V1, and thus canceling voltage CV, to correct values quickly based on overshoot and undershoot voltage measurements. For example, after inductive voltage drop measurements make on only one or two measured voltage pulses of measured arc voltage Uarc_meas, the feedback loop may cancel substantially all of the inductive voltage drop.

Repeating the operations described above across successive welding current pulses for successive welding operations results in the following high-level sequence of operations. Measuring the voltage of successive arc voltage pulses that arise from the successive welding current pulses, to produce successive measured arc voltage pulses including inductive voltage drop, including overshoot and undershoot voltages, due to current ramps of the welding current pulses and inductance of the welding circuit. For each measured arc voltage pulse, canceling the overshoot and undershoot voltages using a canceling voltage to produce a compensated arc voltage, and deriving the canceling voltage based on (i) the magnitude of uncompensated/uncanceled overshoot and undershoot voltage remaining in the compensated arc voltage after the canceling, and (ii) a slope of the current ramps.

The compensation arrived at by the above described operations settles relatively quickly to the correct value of compensation during welding start, but then changes relatively slowly during welding to provide stable compensation that is not easily disturbed. Moreover, the same compensation is also provided between the current pulses on any current waveforms to cancel inductive voltage drop during that time span. Alternative approaches to establish a correct value of compensation at the welding start may use a value of the compensation from a previous welding cycle, use a preset value from a separate measurement or from a calibration procedure before the first welding start, or use a default value.

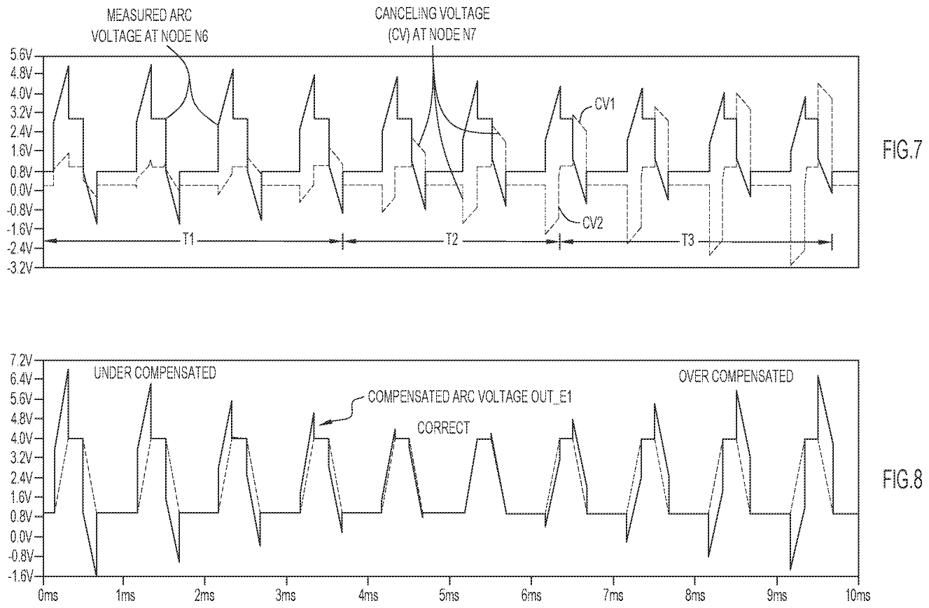

FIGS. 5-8 show example time-aligned current and voltage waveforms at various nodes of inductance compensator 402 during welding operations. FIG. 5 shows a series of current pulses of welding current I1 supplied to node N1 by power supply 102. FIG. 5 also shows inductance voltage/compensation signal V1 superimposed across the current pulses. Inductance voltage V1 controls the magnitude of canceling voltage CV (as depicted in FIG. 7 described below), and is ramped from 0 to 2 volts across the time period of the current pulses to demonstrate the effect of under compensation, correct compensation, and over-compensation.

FIG. 6 shows a series of measured arc voltage pulses (e.g., successive instances of voltage pulse 310) of measured arc voltage Uarc_meas due to the current pulses of welding current I1. The measured arc voltage pulses include inductance-induced overshoot and undershoot voltages OV and UV coinciding with the rising and falling ramps of the current pulses.

FIG. 7 shows canceling voltage CV as measured at node N7 at successive times T1, T2, and T3. Canceling voltage CV includes respective pairs of overshoot and undershoot canceling voltages CV1 and CV2 for each of the measured arc voltage pulses of arc voltage Uarc_meas. Overshoot and undershoot canceling voltages CV1, CV2 coincide with, and are opposite in polarity to, overshoot and undershoot voltages OV, UV, respectively. The magnitude of canceling voltage CV is proportional to inductance voltage V1, which is ramped from 0 to 2V across time periods T1-T3 as shown in FIG. 5, which has the effect described below.

At time T1, the magnitude of canceling voltage CV (i.e., the magnitudes of overshoot and undershoot voltage canceling voltages CV1, CV2) is too low to cancel overshoot and undershoot voltages OV and UV, completely. Thus, overshoot and undershoot voltages OV and UV are under compensated. At time T2, overshoot and undershoot canceling voltages CV1, CV2 mirror corresponding overshoot and undershoot voltages OV and UV, such that the magnitude of canceling voltage CV is just right and cancels substantially all of the overshoot and undershoot voltages. Thus, at time T2, overshoot and undershoot voltages are correctly compensated. This corresponds to the feedback loop operating in its steady state condition. At time T3, the magnitude of canceling voltage CV is too high. In that case, canceling voltage CV re-introduces the overshoot and undershoot voltages, but with polarities that are opposite to their initial polarities. In that case, overshoot and undershoot voltages OV and UV are over compensated.

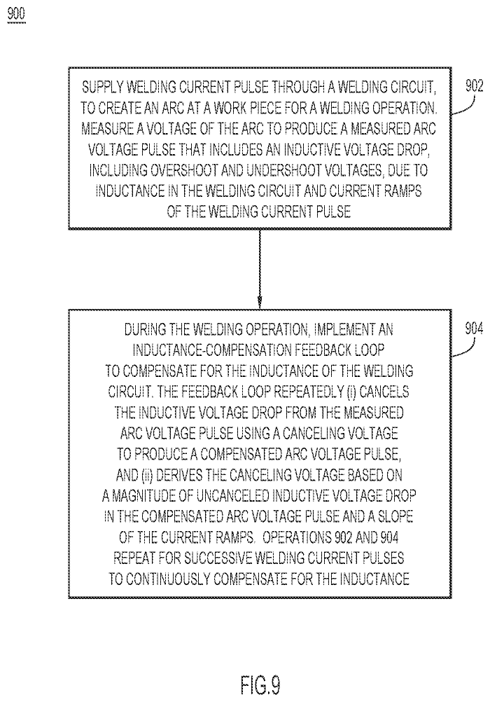

FIG. 8 shows compensated arc voltage Out_E1 after canceling of the overshoot and undershoot voltages OV and UV using canceling voltage CV. At times T1, T2, and T3, compensated arc voltage Out_E1 is under compensated, correctly compensated, and over compensated.

It is understood that the y-axis voltages depicted in FIGS. 6-8 are scaled-down voltages used for simulation purposes. Actual measured and compensated arc voltages corresponding to a 400 A current pulse are typically in a range of 20-40 volts, for example.

FIG. 9 is a flowchart of an example method 900 of inductance compensation performed by a welding system during a welding operation. Method 900 performs the inductance compensation without performing a calibration operation to determine inductance of welding circuit.

At 902, a welding current pulse is supplied through a welding circuit to create an arc at a work piece for a welding operation. A voltage of the arc (i.e., an arc voltage pulse) is measured remotely from the arc, to produce a measured arc voltage pulse that includes an inductive voltage drop, including overshoot and undershoot voltages, due to inductance in the welding circuit and current ramps of the welding current pulse.

At 904, during the welding operation, an inductance-compensation feedback loop is implemented to compensate for the inductance of the welding circuit. That is, the feedback loop operates to cancel the inductive voltage drop from the measured arc voltage pulse. The feedback loop repeatedly performs the following sequence of operations: (i) cancel the inductive voltage drop from the measured arc voltage pulse using a canceling voltage to produce a compensated arc voltage pulse, and (ii) derive the canceling voltage based on the compensated arc voltage pulse. To derive the canceling voltage, the feedback loop concurrently (i) first derives an inductance signal indicative of the inductance based on a magnitude of uncanceled inductive voltage drop remaining in the compensated arc voltage pulse after the canceling, (ii) second derives a slope signal indicative of slope of the current ramps, and (iii) third derives the canceling voltage based on the slope signal and the inductance signal, such that the canceling voltage is time-aligned with the inductive voltage drop, and is equal in magnitude, and opposite in polarity to, the inductive voltage drop. Optionally, the feedback loop, prior to the canceling, lowpass filters the measured arc voltage pulse to reduce high frequency noise on the measured arc voltage pulse, while preserving a shape of the measured arc voltage pulse and the inductance voltage drop.

The welding system (e.g., PSC 104) uses the compensated arc voltage as a basis on which to control parameters of the welding current pulse (or successive welding current pulses).

In the example of FIG. 4, inductance compensator 402 is implemented as an analog circuit that performs signal processing of analog signals. In a digital embodiment, inductance compensator 402 may be implemented digitally. The digital embodiment includes analog-to-digital converters (ADCs) to digitize welding current I1 and measured arc voltage Uarc_meas, to produce current samples and voltage samples, respectively. The digital embodiment includes a processor of PSC 104 to perform digital signal processing on the current and voltage samples to implement the functions of inductance compensator 402 described above. The processor may access memory of PSC 104 that stores/is encoded with software instructions that, when executed by the processor, cause the processor to perform the functions of inductance compensator 402.

An alternative embodiment of inductance indicator 408 is now described. The alternative embodiment of inductance indicator 408 (i) determines a “DC” average of voltage levels of measured arc voltage Uarc_meas before and after the rising ramp of the current pulse (and correspondingly before and after the rising ramp of the measured arc voltage pulse), i.e., when the current is relatively constant just before and during the current pulse, (ii) determines a “ramp” voltage of Uarc_meas coinciding in time with a region of interest on the rising ramp of the current pulse, and (iii) derives inductance voltage V1 based on a difference between the DC average and the ramp voltage.

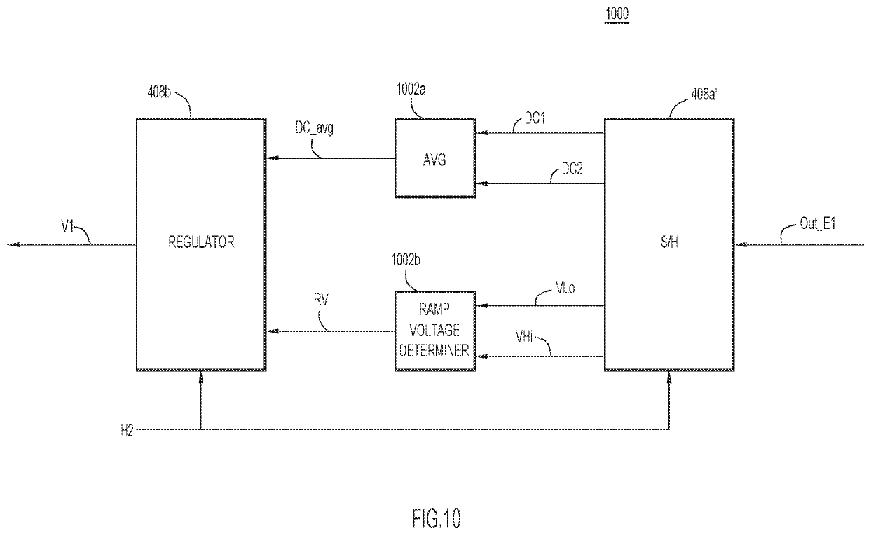

FIG. 10 is an example block diagram of an inductance indicator 1000 according to the alternative embodiment. Inductance indicator 1000 includes sample-and-hold (S/H) module 408a′, regulator 408b′, an averager 1002a, and a ramp voltage determiner 1002b. S/H module 408a′ measures/samples (i) a DC voltage level DC1 of a DC voltage floor (i.e., a minimum DC voltage) preceding the rising ramp of the measured arc voltage pulse, (ii) a DC voltage level DC2 on the DC peak of the measured arc voltage pulse, (iii) a low voltage level VLo of the rising ramp of the measured arc voltage pulse, and (iv) a high voltage level VHi (higher than VLo) of the rising ramp of the measured arc voltage pulse. Averager 1002a computes a DC average DC_avg of DC voltage levels DC1 and DC2, and provides DC_avg to regulator 408b′. Ramp voltage determiner 1002b computes a ramp voltage RV based on (i.e., as a function of) low voltage level VLo and high voltage level VHi, and provides ramp voltage RV to regulator 408b′. Ramp voltage determiner 1002b may compute ramp voltage RV as a function of (VLo+(VHi−VLo)/α), where α>0, e.g., α=1, 2, 3, and so on. For example, when α=2, ramp voltage RV is equal to the average of VLo and VHi. Regulator 408b′ derives inductance voltage V1 based on a difference between DC_avg and ramp voltage RV, that is indicative of inductance, similar to the way regulator 408b derives inductance voltage V1 as described in connection with FIG. 4.

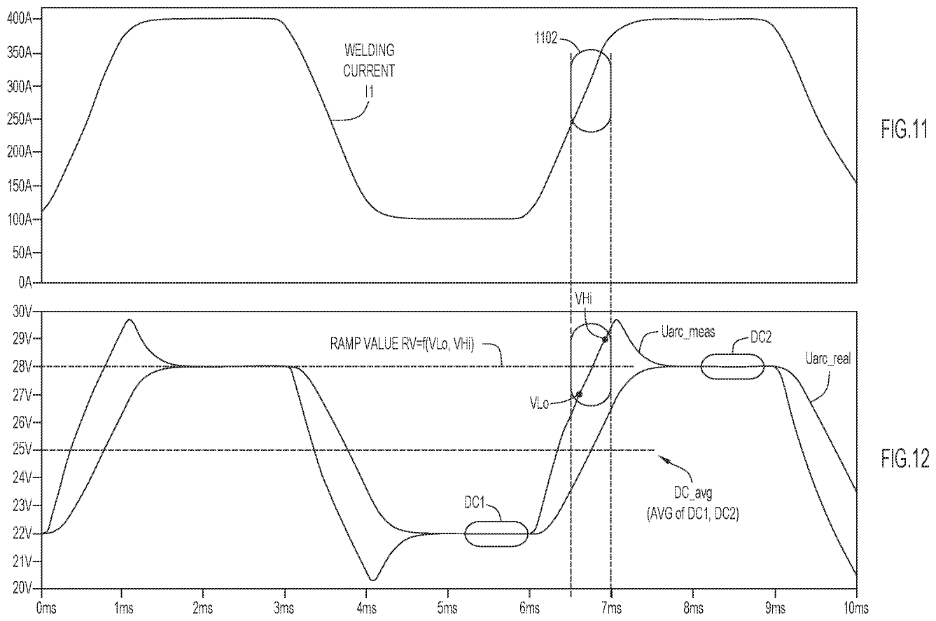

FIG. 11 shows and a current waveform of example current pulses having rising and falling ramps. The current waveform shows a region of interest 1102 on a rising ramp of one of the current pulses during which ramp voltage RV may be determined, as shown in FIG. 12.

FIG. 12 shows voltage waveforms for examples of measured arc voltage Uarc_meas and actual arc voltage Uarc_real corresponding to the current waveform of FIG. 11. FIG. 12 shows examples of voltages/averages DC1, DC2, DC_avg, VHi, VLo, and RV superimposed on the voltage waveforms.

The embodiments presented herein provide continuous compensation of inductive voltage drop in a welding circuit when measuring an arc voltage via a power supply or welding cables that deliver welding current to a welding torch during welding. The embodiments improve accuracy of the measured arc voltage as represented by the compensated arc voltage when inductance of the welding circuit is changing, for example, in welding installations in which welding cables move during welding. Such movement of the welding cables leads to changing inductance in the welding circuit. The embodiments obviate the need for calibration when the welding cable(s) are wound-up or straightened. The embodiments automatically compensate for inductance continuously during the welding operation, without interrupting the welding operation. In the embodiments, lowpass filtering results in a “clean” and reliable compensated arc voltage with minimal ripple. The inductance-compensation feedback loop operates in real-time, and avoids computation delay. Because the inductance voltage/compensation signal (V1) is proportional to welding circuit inductance, the inductance voltage may be used as a measurement of the inductance.

In summary, in one aspect, a method is provided comprising: providing a welding current pulse through a welding circuit to create an arc for a welding operation; measuring an arc voltage to produce a measured arc voltage pulse that includes an inductive voltage drop due to inductance in the welding circuit and current ramps of the welding current pulse; and during the welding operation, implementing an inductance-compensation feedback loop including: canceling the inductive voltage drop from the measured arc voltage pulse using a canceling voltage to produce a compensated arc voltage pulse; and deriving the canceling voltage based on the compensated arc voltage pulse.

In another aspect, an apparatus or system is provided comprising: a power supply to supply a welding current pulse through a welding circuit to produce an arc for a welding operation; and an inductance compensator configured to perform: receiving a measured arc voltage pulse from a sense point at the power supply or the welding circuit, wherein the measured arc voltage pulse includes an inductive voltage drop due to inductance in the welding circuit and current ramps of the welding current pulse; and during the welding operation, implementing an inductance-compensation feedback loop configured to perform: canceling the inductive voltage drop from the measured arc voltage pulse using a canceling voltage to produce a compensated arc voltage pulse; and deriving the canceling voltage based on the compensated arc voltage pulse.

In yet another aspect, a method is provided comprising: providing a welding current pulse through a welding circuit to create an arc for a welding operation; measuring an arc voltage to produce a measured arc voltage pulse that includes an inductive voltage drop due to inductance in the welding circuit and current ramps of the welding current pulse, the inductive voltage drop including an overshoot voltage on a rising voltage ramp of the measured arc voltage pulse and voltage undershoot on a falling voltage ramp of the measured arc voltage; and during the welding operation, implementing an inductance-compensation feedback loop including: canceling the inductive voltage drop, including the overshoot voltage and the undershoot voltage, from the measured arc voltage pulse using a canceling voltage to produce a compensated arc voltage pulse; and deriving the canceling voltage based on a magnitude of uncanceled overshoot voltage and a magnitude of uncanceled undershoot voltage remaining in the compensated arc voltage pulse after the canceling.

In a further aspect, a non-transitory computer readable medium encoded with instructions is provided. The instructions, when executed by a processor, cause the processor to perform the methods presented herein. For example, the processor performs operations to implement the inductance compensator described herein.

Although the techniques are illustrated and described herein as embodied in one or more specific examples, the specific details of the examples are not intended to limit the scope of the techniques presented herein, since various modifications and structural changes may be made within the scope and range of the invention. In addition, various features from one of the examples discussed herein may be incorporated into any other examples. Accordingly, the appended claims should be construed broadly and in a manner consistent with the scope of the disclosure.

What is claimed is:

1. A method comprising:
providing a welding current pulse through a welding circuit to create an arc for a welding operation;
measuring an arc voltage to produce a measured arc voltage pulse that includes an inductive voltage drop due to inductance in the welding circuit and current ramps of the welding current pulse; and
during the welding operation, implementing an inductance-compensation feedback loop including:
canceling the inductive voltage drop from the measured arc voltage pulse using a canceling voltage to produce a compensated arc voltage pulse; and
deriving the canceling voltage based on the compensated arc voltage pulse.

2. The method of claim 1, wherein:
canceling includes summing the canceling voltage with the measured arc voltage pulse; and
deriving includes deriving the canceling voltage to be equal in magnitude and opposite in polarity to the inductive voltage drop.

3. The method of claim 2, wherein deriving further includes:
first deriving an inductance signal that is indicative of inductance of the welding circuit based on the compensated arc voltage pulse;
second deriving, from the welding current pulse, a slope signal that is indicative of a slope of one or more of the current ramps; and
third deriving the canceling voltage based on the inductance signal and the slope signal.

4. The method of claim 3, wherein first deriving the inductance signal includes:
measuring a magnitude of inductive voltage drop remaining in the compensated arc voltage pulse after canceling to produce a measured magnitude, and generating the inductance signal based on the measured magnitude.

5. The method of claim 4, wherein the measured arc voltage pulse includes rising and falling voltage ramps that straddle a direct current (DC) peak of the measured arc voltage pulse, and measuring the magnitude of inductive voltage drop includes:
measuring a difference between levels of (i) a peak of the inductive voltage drop that exceeds the DC peak, and (ii) the DC peak.

6. The method of claim 4, wherein the measured arc voltage pulse includes a rising voltage ramp and a falling voltage ramp that straddle a direct current (DC) peak of the measured arc voltage pulse, and measuring the magnitude of inductive voltage drop includes:
determining a difference between (i) an average of a voltage level of the DC peak of the measured arc voltage pulse and a voltage level of a DC floor of the measured arc voltage, and (ii) an voltage level on the rising voltage ramp.

7. The method of claim 1, further comprising:
prior to canceling, lowpass filtering the measured arc voltage pulse to reduce high frequency noise on the measured arc voltage pulse, while preserving a shape of the measured arc voltage pulse and the inductance voltage drop.

8. The method of claim 1, wherein:
the current ramps include a rising current ramp and the inductive voltage drop includes an overshoot voltage on a rising voltage ramp of the measured arc voltage pulse that coincides with the rising current ramp;
deriving includes deriving an overshoot canceling voltage that is equal in magnitude and opposite in polarity to the overshoot voltage; and
canceling includes summing the overshoot canceling voltage with the overshoot voltage.

9. The method of claim 8, wherein:
deriving the overshoot canceling voltage includes measuring levels of a peak of the overshoot voltage and a DC peak of the measured arc voltage pulse, and deriving the overshoot canceling voltage based on a difference in the levels.

10. The method of claim 1, wherein:
the current ramps include a falling current ramp and the inductive voltage drop includes an undershoot voltage on a falling voltage ramp of the measured arc voltage pulse that coincides with the falling current ramp;
deriving includes deriving an undershoot canceling voltage that is equal in magnitude and opposite in polarity to the undershoot voltage; and
canceling includes summing the undershoot canceling voltage with the undershoot voltage.

11. The method of claim 10, wherein:
deriving the undershoot canceling voltage includes measuring levels of a negative peak of the undershoot voltage and a minimum direct current (DC) level of the measured arc voltage pulse, and deriving the undershoot canceling voltage based on a difference in the levels.

12. The method of claim 1, wherein:
supplying includes supplying the welding current pulse from a welding power supply that generates the welding current pulse to a welding torch through a welding cable having an inductance that causes at least some of the inductive voltage drop; and
measuring includes measuring the arc voltage at a sense point on one of the welding cable or the welding power supply that is spaced-apart from the arc.

13. An apparatus comprising:
a power supply to supply a welding current pulse through a welding circuit to produce an arc for a welding operation; and
an inductance compensator configured to perform:
receiving a measured arc voltage pulse from a sense point at the power supply or the welding circuit, wherein the measured arc voltage pulse includes an inductive voltage drop due to inductance in the welding circuit and current ramps of the welding current pulse; and
during the welding operation, implementing an inductance-compensation feedback loop configured to perform:
canceling the inductive voltage drop from the measured arc voltage pulse using a canceling voltage to produce a compensated arc voltage pulse; and
deriving the canceling voltage based on the compensated arc voltage pulse.

14. The apparatus of claim 13, wherein the inductance compensator is configured to perform:
canceling by summing the canceling voltage with the measured arc voltage pulse; and
deriving by deriving the canceling voltage to be equal in magnitude and opposite in polarity to the inductive voltage drop.

15. The apparatus of claim 14, wherein the inductance compensator is configured to further perform deriving by:
first deriving an inductance signal that is indicative of inductance of the welding circuit based on the compensated arc voltage pulse;
second deriving, from the welding current pulse, a slope signal that is indicative of a slope of one or more of the current ramps; and
third deriving the canceling voltage based on the inductance signal and the slope signal.

16. The apparatus of claim 15, wherein the inductance compensator is configured to perform first deriving by:
measuring a magnitude of inductive voltage drop remaining in the compensated arc voltage pulse after canceling to produce a measured magnitude, and generating the inductance signal based on the measured magnitude.

17. The apparatus of claim 16, wherein the measured arc voltage pulse includes rising and falling voltage ramps that straddle a DC peak of the measured arc voltage pulse, and the inductance compensator is configured to perform measuring the magnitude of inductive voltage drop by:
measuring a difference between levels of a peak of the inductive voltage drop that exceeds the DC peak, and the DC peak.

18. The apparatus of claim 13, wherein:
the current ramps include a rising current ramp and the inductive voltage drop includes an overshoot voltage on a rising voltage ramp of the measured arc voltage pulse that coincides with the rising current ramp;
the inductance compensator is configured to perform deriving by deriving an overshoot canceling voltage that is equal in magnitude and opposite in polarity to the overshoot voltage; and
the inductance compensator is configured to perform canceling by summing the overshoot canceling voltage with the overshoot voltage.

19. The apparatus of claim 18, wherein the inductance compensator is configured to perform deriving the overshoot canceling voltage by:
measuring levels of a peak of the overshoot voltage and a DC peak of the measured arc voltage pulse; and
deriving the overshoot canceling voltage based on a difference in the levels.

20. The apparatus of claim 13, wherein:
the current ramps include a falling current ramp and the inductive voltage drop includes an undershoot voltage on a falling voltage ramp of the measured arc voltage pulse that coincides with the falling current ramp;
the inductance compensator is configured to perform deriving by deriving an undershoot canceling voltage that is equal in magnitude and opposite in polarity to the undershoot voltage; and
the inductance compensator is configured to perform canceling by summing the undershoot canceling voltage with the undershoot voltage.

21. The apparatus of claim 20, wherein the inductance compensator is configured to perform deriving the undershoot canceling voltage by:
measuring levels of a negative peak of the undershoot voltage and a minimum direct current (DC) level of the measured arc voltage pulse; and
deriving the undershoot canceling voltage based on a difference in the levels.

22. The apparatus of claim 13, wherein the welding circuit includes:
a welding cable coupled to the power supply and a welding torch to deliver the welding current pulse to the welding torch,
wherein the inductive voltage drop arises at least in part from inductance of the welding cable.
